(19) United States
(12) Patent Application Publication
(10) Pub. No.: US 2025/0386718 A1
(43) Pub. Date: Dec. 18, 2025

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Bo SHI, Beijing (CN); Tiaomei ZHANG, Beijing (CN); Jianji FU, Beijing (CN); Yuanhao TAN, Beijing (CN); Xinghao XUE, Beijing (CN); Gukhwan SONG, Beijing (CN); Zhiliang JIANG, Beijing (CN); Kailong ZUO, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 19/126,664

(22) PCT Filed: Oct. 24, 2024
(86) PCT No.: PCT/CN2024/127131

§ 371 Date: May 2, 2025

(30) Foreign Application Priority Data
Nov. 22, 2023 (CN) 202311568594.1

(51) Int. Cl. H10K 59/80; H10K 59/122; H10K 59/38; H10K 59/40

(52) U.S. Cl. CPC H10K 59/879; H10K 59/122; H10K 59/38; H10K 59/40; H10K 59/873; H10K 59/8792

(57) ABSTRACT

Provided is a display panel and a display device. The display panel includes a display substrate, a first dimming layer, and a second dimming layer, and the display substrate includes a base substrate and multiple pixel units. The refractive index of the first dimming layer is different from the refractive index of the second dimming layer, and the first dimming layer and the second dimming layer are disposed at least in the display region. The second dimming layer includes a first target portion with a continuous film layer disposed in the display region and the transition region, wherein a first boundary of the first target portion close to the hole region is disposed within the transition region, and a distance between the first boundary and the display region is less than a distance between the first boundary and the hole region.

### CROSS-REFERENCE TO RELATED APPLICATIONS

This application is a U.S. national stage of international application No. PCT/CN2024/127131, filed on Oct. 24, 2024, and claims priority to Chinese Patent Application No. 202311568594.1, filed on Nov. 22, 2023, and entitled “DISPLAY PANEL AND DISPLAY DEVICE”, the contents of each are incorporated herein by reference in its entirety.

### TECHNICAL FIELD

The present disclosure relates to the field of display technologies, and in particular, relates to a display panel and a display device.

### BACKGROUND

The display panel includes a base substrate and pixel units disposed in a display region of the base substrate. The pixel units are capable of emitting light, thereby enabling the display panel to perform display functions.

SUMMARY

The present disclosure provides a display panel and a display device, and the technical solutions are given as follows.

In one aspect, a display panel is provided, and the display panel includes a display substrate. The display substrate includes:
a base substrate having a hole region, a transition region surrounding the hole region, and a display region surrounding the transition region;
and multiple pixel units disposed on one side of the base substrate and in the display region;
the display panel further includes: a first dimming layer and a second dimming layer sequentially stacked on a side of the multiple pixel units away from the base substrate, wherein a refractive index of the first dimming layer is different from a refractive index of the second dimming layer, and the first dimming layer and the second dimming layer are disposed at least in the display region;
wherein the second dimming layer includes a first target portion with a continuous film layer disposed in the display region and the transition region, a first boundary of the first target portion close to the hole region is disposed within the transition region, and a distance between the first boundary and the display region is less than a distance between the first boundary and the hole region.

In some embodiments, the first dimming layer includes a second target portion with a continuous film layer disposed in the transition region, a second boundary of the second target portion close to the hole region is disposed within the transition region, and a distance between the second boundary and the display region is less than a distance between the second boundary and the hole region.

In some embodiments, the second boundary is farther from the display region than the first boundary is, and an orthographic projection of the first boundary on the base substrate is within an orthographic projection of the second target portion on the base substrate; or
the first boundary is farther from the display region than the second boundary is, and an orthographic projection of the first target portion on the base substrate covers an orthographic projection of the second boundary on the base substrate.

In some embodiments, the display panel further includes a color filter layer and a first planarization layer stacked in sequence away from the display substrate between the display substrate and the first dimming layer; wherein
the color filter layer includes multiple color resistors disposed in the display region and a black matrix disposed in the display region, wherein an orthographic projection of each color resistor on the base substrate overlaps with an orthographic projection of a light-emitting region of a pixel unit corresponding to the color resistor on the base substrate, light emitted from the pixel unit exits after passing through the color resistor, and an orthographic projection of the black matrix on the base substrate is disposed between light-emitting regions of adjacent pixel units; and
the first planarization layer includes a third target portion with a continuous film layer disposed in the display region and the transition region, wherein a third boundary of the third target portion close to the hole region is disposed within the transition region, and a distance between the third boundary and the display region is less than a distance between the third boundary and the hole region.

In some embodiments, the second boundary is farther from the display region than the first boundary is, and the third boundary is farther from the display region than the second boundary is; and
an orthographic projection of the first boundary on the base substrate is within an orthographic projection of the second target portion on the base substrate, and an orthographic projection of the second boundary on the base substrate is within an orthographic projection of the third target portion on the base substrate.

In some embodiments, the second boundary is farther from the display region than the third boundary is, and the first boundary is farther from the display region than the second boundary is; and
an orthographic projection of the first target portion on the base substrate covers an orthographic projection of the second boundary on the base substrate, and an orthographic projection of the second target portion on the base substrate covers an orthographic projection of the third boundary on the base substrate.

In some embodiments, the third boundary is farther from the display region than the second boundary is, and the first boundary is farther from the display region than the third boundary is; and
an orthographic projection of the second boundary on the base substrate is within an orthographic projection of the third target portion on the base substrate, and an orthographic projection of the first target portion on the base substrate covers an orthographic projection of the second boundary on the base substrate and covers an orthographic projection of the third boundary on the base substrate.

In some embodiments, the second dimming layer further includes multiple first dimming island-shaped patterns evenly spaced in the transition region; and
the multiple first dimming island-shaped patterns are closer to the hole region than the first target portion is and any of the multiple first dimming island-shaped patterns is spaced from the first target portion.

In some embodiments, the first dimming layer includes a second target portion with a continuous film layer disposed in the transition region, a second boundary of the second target portion close to the hole region is disposed within the transition region; and
the second boundary is farther from the display region than the multiple first dimming island-shaped patterns are, and an orthographic projection of the multiple first dimming island-shaped patterns on the base substrate is within an orthographic projection of the second target portion on the base substrate.

In some embodiments, the first dimming layer includes a second target portion with a continuous film layer disposed in the transition region, a second boundary of the second target portion close to the hole region is disposed within the transition region; the second boundary is farther from the display region than the first boundary is, and an orthographic projection of the first boundary on the base substrate is within an orthographic projection of the second target portion on the base substrate; and
the first dimming layer further includes multiple second dimming island-shaped patterns evenly spaced in the transition region, the multiple second dimming island-shaped patterns are farther from the display region than the second target portion is, and any of the multiple second dimming island-shaped patterns is spaced from the second target portion.

In some embodiments, the display panel further includes a first planarization layer disposed between the display substrate and the first dimming layer, wherein the first dimming layer and the first planarization layer are made of different materials;
the first planarization layer has multiple island-shaped recesses evenly spaced in a portion where its orthographic projection on the base substrate neither overlaps with an orthographic projection of the first target portion on the base substrate nor overlaps with an orthographic projection of the second target portion on the base substrate; and
the first dimming layer includes multiple third dimming island-shaped patterns corresponding to the multiple island-shaped recesses, each of the multiple third dimming island-shaped patterns being disposed within an island-shaped recess corresponding to the third dimming island-shaped pattern.

In some embodiments, the second dimming layer further includes multiple first dimming ring patterns spaced in the transition region, an orthographic projection of the multiple first dimming ring patterns on the base substrate surrounds the hole region and the multiple first dimming ring patterns are farther from the display region than the first target portion is, and any of the multiple first dimming ring patterns is spaced from the first target portion;
the first dimming layer further includes multiple second dimming ring patterns spaced in the transition region, an orthographic projection of the multiple the second dimming ring patterns on the base substrate surrounds the hole region and the multiple the second dimming ring patterns are farther from the display region than the second target portion is, and any of the multiple second dimming ting patterns is spaced from the second target portion;
wherein the multiple first dimming ring patterns and the multiple second dimming ring patterns are arranged in a staggered manner.

In some embodiments, the first dimming layer includes multiple strip-shaped recesses disposed in the transition region, and the multiple strip-shaped recesses are evenly spaced around the hole region; and
the second dimming layer includes multiple dimming strip-shaped patterns corresponding to the multiple strip-shaped recesses, each dimming strip-shaped pattern being disposed within a strip-shaped recess corresponding to the dimming strip-shaped pattern.

In some embodiments, the display substrate further includes a first organic functional layer disposed on one side of the base substrate, the first organic functional layer being disposed in the display region and the transition region; and the display substrate further includes a first isolation pillar, a first barrier structure and a second isolation pillar in the transition region disposed sequentially in a direction away from the display region;
wherein the first organic functional layer is broken at at least one of the first isolation pillar and the second isolation pillar.

In some embodiments, the display substrate includes: a buffer layer, an active layer, a first gate insulation layer, a first gate layer, a second gate insulation layer, a second gate layer, an inter layer dielectric layer, a first source-drain layer, a first planarization layer, a second source-drain layer, a second planarization layer, an anode layer, a pixel definition layer, a support layer, a light-emitting layer, a cathode layer, and an encapsulation layer that are stacked in sequence in a direction away from the base substrate;
the light-emitting layer includes the first organic functional layer, a second organic functional layer, and a light-emitting pattern, the first organic functional layer including a hole transport layer and an electron transport layer, and the second organic functional layer including a hole injection layer and an electron injection layer; and
the encapsulation layer includes a first inorganic encapsulation layer, an organic encapsulation layer, and a second inorganic encapsulation layer that are stacked in sequence, the first inorganic encapsulation layer and the second inorganic encapsulation layer being disposed in the display region, the periphery region, and the transition region, and the organic encapsulation layer being disposed on a side, close to the display region, of the first barrier structure.

In some embodiments, the first isolation pillar and the second isolation pillar both include a target film layer; wherein
the target film layer is disposed in the first source-drain layer, and an orthographic projection of the target film layer on a reference plane is I-shaped, the reference plane being perpendicular to a bearing surface of the base substrate.

In some embodiments, the display substrate includes multiple second isolation pillars;
a distance between an orthographic projection of the first boundary on the base substrate and an orthographic projection of a centerline of one of the multiple second isolation pillars closest to the display region on the base substrate is greater than or equal to 100 micrometers.

In some embodiments, the display panel further includes a touch substrate and a second planarization layer disposed between the display substrate and the first dimming layer and stacked in a direction away from the display substrate;
the touch substrate includes a first touch electrode layer, a touch insulation layer, and a second touch electrode layer that are stacked in sequence; and
one of the first touch electrode layer and the second touch electrode layer includes a bridging electrode of multiple first touch electrodes, and another includes multiple second touch electrodes and a body electrode of the multiple first touch electrodes, and the bridging electrode and the body electrode are electrically connected through a via hole in the touch insulation layer.

In some embodiments, the second planarization layer includes a fourth target portion with a continuous film layer disposed in the display region and the transition region, a fourth boundary of the fourth target portion close to the hole region is disposed within the transition region, and a distance between the fourth boundary and the display region is less than a distance between the fourth boundary and the hole region.

In another aspect, a display device is provided, the display device includes a power assembly and a display panel as described in the above embodiments;
wherein the power assembly is configured to power the display panel.

### BRIEF DESCRIPTION OF THE DRAWINGS

To describe technical solutions in the embodiments of the present disclosure more clearly, the following briefly introduces the accompanying drawings required for describing the embodiments. Apparently, the accompanying drawings in the following description illustrate merely some embodiments of the present disclosure, and a person of ordinary skill in the art may still derive other drawings from these accompanying drawings without creative efforts.

FIG. 1 is a schematic structural diagram of a display panel according to some embodiments of the present disclosure;

FIG. 2 is a top view of a base substrate according to some embodiments of the present disclosure;

FIG. 3 is a schematic structural diagram of a display panel disposed in a display region according to some embodiments of the present disclosure;

FIG. 4 is a schematic structural diagram of a display panel according to some embodiments of the present disclosure;

FIG. 5 is a schematic structural diagram of a display panel according to some embodiments of the present disclosure;

FIG. 6 is a schematic structural diagram of a display panel according to some embodiments of the present disclosure;

FIG. 7 is a schematic structural diagram of a display panel according to some embodiments of the present disclosure;

FIG. 8 is a schematic structural diagram of a display panel according to some embodiments of the present disclosure;

FIG. 9 is a schematic structural diagram of a display panel according to some embodiments of the present disclosure;

FIG. 10 is a top view of a display panel disposed in a transition region according to some embodiments of the present disclosure;

FIG. 11 is a schematic structural diagram of a display panel according to some embodiments of the present disclosure;

FIG. 12 is a top view of a display panel disposed in a transition region according to some embodiments of the present disclosure;

FIG. 13 is a schematic structural diagram of a display panel according to some embodiments of the present disclosure;

FIG. 14 is a top view of a display panel disposed in a transition region according to some embodiments of the present disclosure;

FIG. 15 is a schematic structural diagram of a display panel according to some embodiments of the present disclosure;

FIG. 16 is a top view of a display panel disposed in a transition region according to some embodiments of the present disclosure;

FIG. 17 is a schematic structural diagram of a display panel according to some embodiments of the present disclosure;

FIG. 18 is a schematic partial diagram of a target film layer and a first organic functional layer according to some embodiments of the present disclosure;

FIG. 19 is a schematic partial diagram of a touch substrate according to some embodiments of the present disclosure; and

FIG. 20 is a schematic structural diagram of a display device according to some embodiments of the present disclosure.

### DETAILED DESCRIPTION

To make the technical solutions and advantages of the present disclosure clearer, the embodiments of the present disclosure will be described in further detail below with reference to the accompanying drawings.

In the related art, the display panel further includes a dimming layer disposed in the display region, the dimming layer is capable of converging the light from the edge region of the pixel unit to increase the forward light output of the pixel unit.

However, the dimming layer is prone to warping during the subsequent preparation of film layers, which may pull other film layers in the display panel, resulting in separation between film layers in the display panel and a lower yield rate of the display panel.

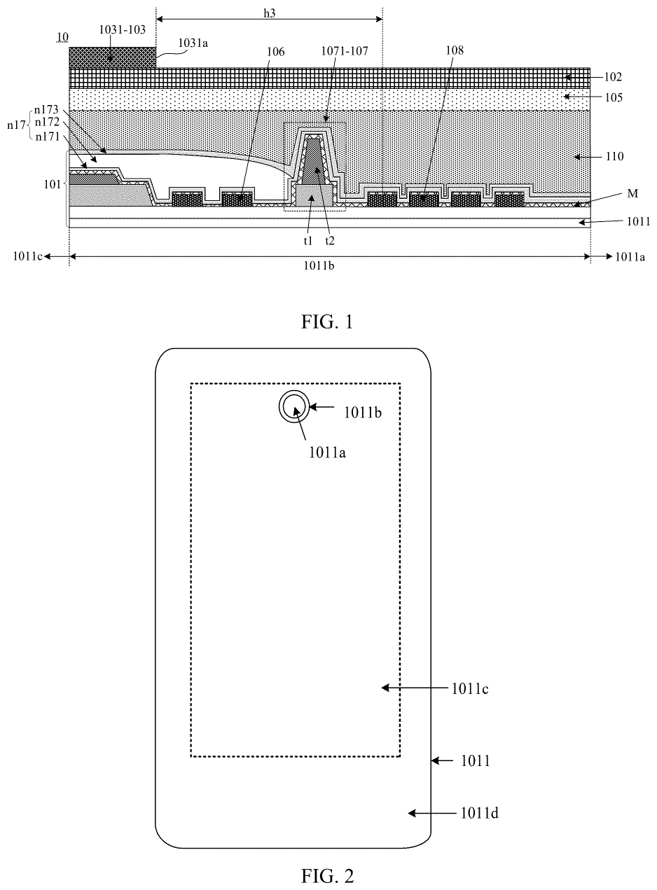

FIG. 1 is a schematic structural diagram of a display panel according to some embodiments of the present disclosure. Referring to FIG. 1, the display panel 10 includes a display substrate 101, a first dimming layer 102, and a second dimming layer 103. The display substrate 101 includes a base substrate 1011 and multiple pixel units 1012.

FIG. 2 is a top view of a base substrate according to some embodiments of the present disclosure. With reference to FIGS. 1 and 2, the base substrate 1011 is provided with a hole region 1011a, a transition region 1011b surrounding the hole region 1011a, and a display region 1011c surrounding the transition region 1011b.

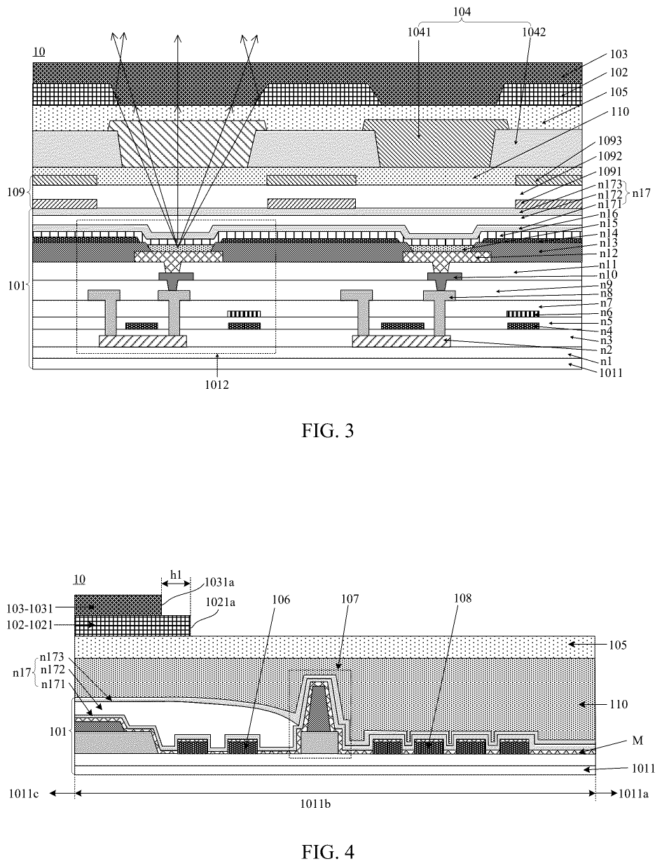

FIG. 3 is a schematic structural diagram of a display panel disposed in a display region according to some embodiments of the present disclosure. With reference to FIGS. 1 to 3, the multiple pixel units 1012 are disposed on one side of the base substrate 1011 and disposed in the display region 1011c. The multiple pixel units 1012 are used to emit light, thereby realizing the display function of the display panel 10. The first dimming layer 102 and the second dimming layer 103 are sequentially stacked on the side of the multiple pixel units 1012 away from the substrate 1011. The first dimming layer 102 and the second dimming layer 103 are disposed at least in the display region 1011c. And, the portion, disposed in the display region 1011c, of the first dimming layer 102 and the second dimming layer 103 is used to dim the light emitted from the pixel units 1012 to increase the light output of the pixel units 1012, to increase the luminous intensity of the display panel 10, thereby enhancing the display effect. In some embodiments, the material of the first dimming layer 102 and the material of the second dimming layer 103 are both optical cement (OC).

In some embodiments, the refractive index of the first dimming layer 102 is different from the refractive index of the second dimming layer 103. In the display region 1011c, when the light rays from the edge region of the pixel units 1012 are irradiated to the interface of the first dimming layer 102 and the second dimming layer 103, the light rays may be refracted, and the direction of refraction is closer to the target direction (the target direction is perpendicular to the bearing surface of the base substrate 1011) with respect to the incident direction. That is, the first dimming layer 102 and the second dimming layer 103 may converge the light rays from the edge region of the pixel units 1012 to increase the forward light output of the pixel units 1012.

During the preparation process of the display panel 10, after the second dimming layer 103 is fabricated, the entire structure may need to be treated in a high-temperature or high-humidity environment in the subsequent preparation of the other film layers. High temperature may mean above 85° C. (Celsius) and high humidity may mean above 85%. Further, due to the special nature of the material of the second dimming layer 103, the physical properties of the second dimming layer 103 are likely to change (such as expansion and generation of pulling force) in a high-temperature or high-humidity environment, which may cause the display panel to warp. In some embodiments, the material of the second dimming layer 103 may be zirconia particles with fine particles added to the organic resin.

Typically, the pulling force generated by the second dimming layer 103 is likely to cause the film layers in the display panel 10 to peel off. Moreover, if the film layers peel off, it is more likely to allow water vapor or oxygen to invade the display region 1011c along the surface of the separated film layer, resulting in the appearance of hole black spots (black spots on the edge of the holes, GDSH) in the display region 1011c of the display panel. The display effect is poor, and in severe cases, the product will be scrapped. Further, if the physical properties of the second dimming layer 103 change, the portion of the film layers, located in the transition region 1011b near the hole region 1011a, in the display substrate 101 is more likely to peel off. And since the sidewall of the hole region 1011a is exposed, water vapor and oxygen are more likely to invade the display region 1011c from the sidewall of the hole region 1011a through the transition region 1011b. Therefore, in order to ensure the display effect of the display panel, the portion of the second dimming layer 103 disposed in the transition region 1011b needs to be designed to prevent the display panel from warping and thus avoid the invasion of water vapor and oxygen caused by the peeling of the film layers.

In some embodiments of the present disclosure, the second dimming layer 103 includes a first target portion 1031 with a continuous film layer disposed in the display region 1011c and the transition region 1011b. The first boundary 1031a of the first target portion 1031 close to the hole region 1011a is disposed within the transition region 1011b, and the distance between the first boundary 1031a and the display region 1011c is less than the first distance between the first boundary 1031a and the hole region 1011a. That is, the first boundary 1031a of the first target portion 1031 of the continuous film layer in the second dimming layer 103 is closer to the display region 1011c than to the hole region 1011a. As the distance between the first target portion 1031 and the hole region 1011a is relatively long, the pulling force generated by the expansion of the first target portion 1031 has less influence on the hole region 1011a.

As a result, in the subsequent high-temperature or high-humidity process of forming the display panel 10, even if the second dimming layer 103 expands and generates a pulling force, it will not have a significant impact on the hole region 1011a, thereby reducing the possibility of separation of the film layer in the display panel 10 and improving the yield rate of the display panel 10.

In summary, the embodiments of the present disclosure provide a display panel, the display panel includes a display substrate, a first dimming layer, and a second dimming layer, and the display substrate includes a base substrate and multiple pixel units. The refractive index of the first dimming layer is different from the refractive index of the second dimming layer, so that the light emitted by the pixel units is converged, thereby increasing the forward light output of the pixel units and improving the display effect of the display panel. Moreover, since the distance between the first boundary of the first target portion, which is included in the second dimming layer and has a continuous film layer located in the display region and the transition region, and the hole region is longer, the influence of the pulling force generated by the expansion of the first target portion of the second dimming layer on the hole region is reduced, thereby reducing the possibility of separation of the film layer in the display panel and improving the yield rate of the display panel.

Referring to FIG. 4, the first dimming layer 102 includes a second target portion 1021 with a continuous film layer disposed in the transition region 1011b. A second boundary of the second target portion 1021 close to the hole region 1011a is disposed within the transition region 1011b, and the distance between the second boundary 1021a and the display region 1011c is less than the distance between the second boundary 1021a and the hole region 1011a.

Since the first dimming layer 102 is disposed between the second dimming layer 103 and the display substrate 101, the first dimming layer 102 serves as an intermediate transfer layer for the pulling force generated by the second dimming layer 103, and the first dimming layer 102 transfers the pulling force generated by the second dimming layer 103 to the display substrate 101. Therefore, by designing a larger distance between the second target portion 1021 of the first dimming layer 102 and the hole region 1011a, the transfer effect of the pulling force when the first dimming layer 102 acts as the intermediate transfer layer is reduced, thereby reducing the possibility of separation of the film layer and improving the yield rate of the display panel 10.

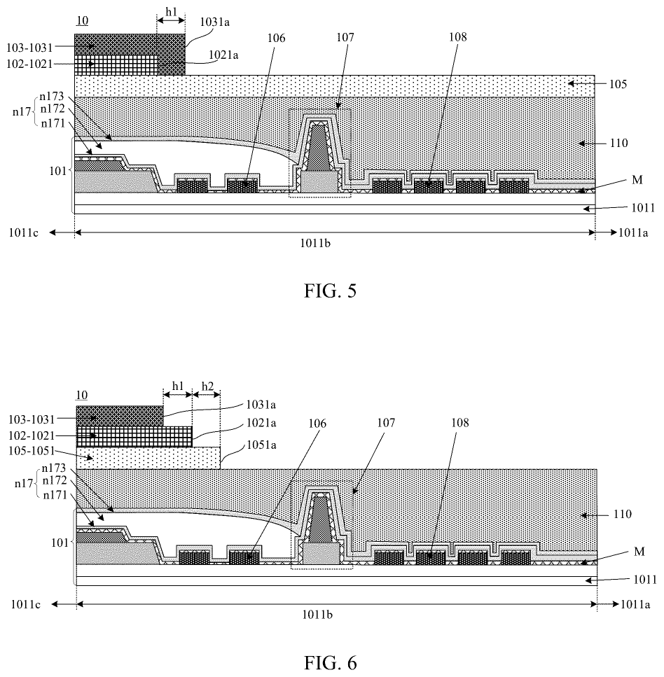

Referring to FIG. 4, the second boundary 1021a is farther from the display region 1011c than the first boundary 1031a is, and the orthographic projection of the first boundary 1031a on the base substrate 1011 is within the orthographic projection of the second target portion 1021 on the base substrate 1011. Alternatively, referring to FIG. 5, the first boundary 1031a is farther from the display region 1011c than the second boundary 1021a is, and the orthographic projection of the first target portion 1031 on the base substrate 1011 covers the orthographic projection of the second boundary 1021a on the base substrate 1011.

In some embodiments, for FIG. 4 and FIG. 5, the distance h1 between the first boundary 1031a and the second boundary 1021a is greater than or equal to 10 μm (micrometers). That is, in FIG. 4, the first target portion 1031 is at least inwardly retracted by 10 μm relative to the second target portion 1021 in the direction away from the hole region 1011a. In FIG. 5, the first target portion 1031 is at least wrapped to 10 μm relative to the second target portion 1021 in the direction close to the hole region 1011a.

Referring to FIG. 3, the display panel 10 further includes a color filter layer 104 and a first planarization layer 105 disposed between the display substrate 101 and the first dimming layer 102 and stacked in the direction away from the display substrate 101.

The color filter layer 104 includes multiple color resistors 1041 disposed in the display region 1011c and a black matrix 1042 disposed in the display region 1011c. The orthographic projection of each color resistor 1041 on the base substrate 1011 overlaps with the orthographic projection of a light-emitting region of the pixel unit 1012 corresponding to the color resistor 1041 on the base substrate, and the light emitted from the pixel unit 1012 exits after passing through the color resistor 1041. The orthographic projection of the black matrix 1042 on the base substrate 1011 is disposed between light-emitting regions of adjacent pixel units 1012.

In some embodiments, the black matrix 1042 is provided with multiple openings. Each opening is used to expose one of the color resistors 1041. The orthographic projection of each color resistor 1041 on the base substrate 1011 covers the light-emitting region of the pixel unit 1012 corresponding to the color resistor. The light emitted by the pixel unit 1012 exits after passing through the corresponding color resistor 1041.

Referring to FIG. 6, the first planarization layer 105 includes a third target portion 1051 with a continuous film layer disposed in the display region 1011c and the transition region 1011b, a third boundary 1051a of the third target portion 1051 close to the hole region 1011a is disposed within the transition region 1011b, and a distance between the third boundary 1051a and the display region 1011c is less than a distance between the third boundary 1051a and the hole region 1011a.

Since the first planarization layer 105 is disposed between the second dimming layer 103 and the display substrate 101, the first planarization layer 105 also serves as an intermediate transfer layer for the pulling force generated by the second dimming layer 103, and the first planarization layer 105 transfers the pulling force generated by the second dimming layer 103 to the display substrate 101. Therefore, by designing a larger distance between the third target portion of the first planarization layer 105 and the hole region 1011a, the transfer effect of the pulling force when the first planarization layer 105 acts as the intermediate transfer layer is reduced, thereby reducing the possibility of separation of the film layer and improving the yield rate of the display panel 10.

Referring to FIG. 6, the second boundary 1021a is farther from the display region 1011c than the first boundary 1031a is, and the third boundary 1051a is farther from the display region 1011c than the second boundary 1021a is. The orthographic projection of the first boundary 1031a on the base substrate 1011 is disposed within the orthographic projection of the second target portion 1021 on the substrate 1011, and the orthographic projection of the second boundary 1021a on the base substrate 1011 is disposed within the orthographic projection of the third target portion 1051 on the base substrate 1011.

That is, the third target portion 1051, the second target portion 1021, and the first target portion 1031 are sequentially inwardly in the direction away from the hole region 1011a. In some embodiments, the distance h1 between the first boundary 1031a and the second boundary 1021a is greater than or equal to 10 μm, and the distance h2 between the second boundary 1021a and the third boundary 1051a is greater than or equal to 10 μm. That is, in FIG. 6, the first target portion 1031 is inwardly retracted by at least 10 μm with respect to the second target portion 1021 in the direction away from the hole region 1011a, the second target portion 1021 is inwardly retracted by at least 10 μm relative to the third target portion 1051 in the direction away from the hole region 1011a.

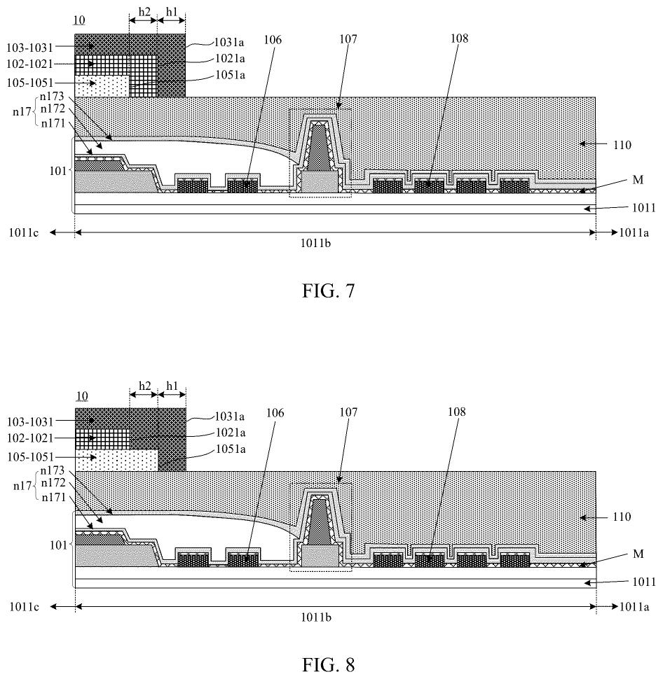

Referring to FIG. 7, the second boundary 1021a is farther from the display region 1011c than the third boundary 1051a is, and the first boundary 1031a is farther from the display region 1011c than the second boundary 1021a is. The orthographic projection of the first target portion 1031 on the base substrate 1011 covers the orthographic projection of the second boundary 1021a on the base substrate 1011, and the orthographic projection of the second target portion 1021 on the base substrate 1011 covers the orthographic projection of the third boundary 1051a on the base substrate 1011.

That is, the first target portion 1031, the second target portion 1021, and the third target portion 1051 are sequentially wrapped in the direction close to the hole region 1011a. In some embodiments, the distance h1 between the first boundary 1031a and the second boundary 1021a is greater than or equal to 10 μm, and the distance h2 between the second boundary 1021a and the third boundary 1051a is greater than or equal to 10 μm. That is, in FIG. 7, the first target portion 1031 is wrapped for at least 10 μm with respect to the second target portion 1021 in the direction close to the hole region 1011a, the second target portion 1021 is wrapped at least 10 μm relative to the third target portion 1051 in the direction close to the hole region 1011a.

Referring to FIG. 8, the third boundary 1051a is farther from the display region 1011c than the second boundary 1021a is, and the first boundary 1031a is farther from the display region 1011c than the third boundary 1051a is. The orthographic projection of the second boundary 1021a on the base substrate 1011 is disposed within the orthographic projection of the third target portion 1051 on the base substrate 1011, and the orthographic projection of the first target portion 1031 on the base substrate 1011 covers the orthographic projection of the second boundary 1021a on the base substrate 1011 and covers the orthographic projection of the third boundary 1051a on the base substrate 1011.

That is, the second target portion 1021 is inwardly retracted with respect to the third target portion 1051 in the direction away from the hole region 1011a, and the first target portion 1031 is wrapped with respect to the second target portion 1021 as well as the third target portion 1051 in the direction close to the hole region 1011a. In some embodiments, the distance h2 between the second boundary 1021a and the third boundary 1051a is greater than or equal to 10 μm, and the distance h1 between the first boundary 1031a and the third boundary 1051a is greater than or equal to 10 μm. That is, in FIG. 8, the second target portion 1021 is inwardly retracted in the direction away from the hole region 1011a by at least 10 μm relative to the third target portion 1051, the first target portion 1031 is wrapped at least 10 μm relative to the third target portion 1051 in the direction close to the hole region 1011a.

In the embodiments of the present disclosure, in the above-described FIG. 1 and FIGS. 4 to 8, the distance between the first boundary 1031a of the first target portion 1031, the second boundary 1021a of the second target portion 1021, and the third boundary 1051a of the third target portion 1051 and the hole region 1011a are all larger (the region being hollowed out is larger), this may result in poor surface flatness of the second dimming layer 103 in the display panel 10. When attaching a glass substrate to the second dimming layer 103 away from the base substrate 1011 using an adhesive material in subsequent processes, a relatively large amount of adhesive material is required to fill the surface, leading to poor flexibility.

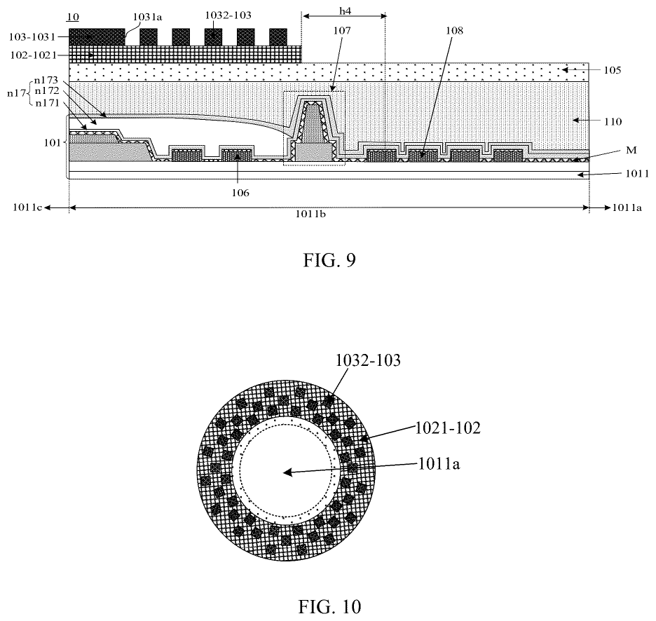

For the above reasons, as the first optional implementation, referring to FIG. 9, the second dimming layer 103 further includes multiple first dimming island-shaped patterns 1032 evenly spaced in the transition region 1011b. The multiple first dimming island-shaped patterns 1032 are closer to the hole region 1011a than the first target portion 1031 is, and any of the first dimming island-shaped patterns 1032 is spaced from the first target portion 1031. By designing the first dimming island-shaped patterns 1032, the flatness of the display panel 10 is improved, so that less adhesive material is used to fill the surface, resulting in better flexibility.

Moreover, since any of the first dimming island-shaped patterns 1032 is spaced from the first target portion 1031, the pulling force generated by the expansion of the first target portion 1031 is not transferred to the hole region 1011a through the first dimming island-shaped patterns 1032. And since the first dimming island-shaped pattern 1032 is relatively smaller in size compared to the entire film layer, so the pulling force generated by their expansion is relatively small. Such a small pulling force has minimal impact on the hole area 1011a and is less likely to cause film layer separation in the display panel 10.

Further, since the pulling force generated by the first dimming island-shaped pattern 1032 is small, even if the first dimming layer 102 (intermediate transfer layer) is set below the first dimming island-shaped pattern 1032, it does not cause a significant impact on the hole area 1011a, thereby improving the surface flatness.

Thus, referring to FIGS. 9 and 10, the first dimming layer 102 includes a second target portion 1021 with a continuous film layer disposed in the transition region 1011b, and the second boundary 1021a of the second target portion 1021 close to the hole region 1011a is disposed within the transition region 1011b. The second boundary 1021a of the second target portion 1021 included in the first dimming layer 102 is farther from the display region 1011c than the multiple first dimming island-shaped patterns 1032 is. The orthographic projection of the multiple first dimming island-shaped patterns 1032 on the base substrate 1011 is disposed within the orthographic projection of the second target portion 1021 on the base substrate 1011.

In some embodiments, referring to FIG. 10, the shape of the orthographic projection of the first dimming island-shaped pattern 1032 on the base substrate 1011 is a square. The shape of the orthographic projection of the first dimming island-shaped pattern 1032 on the base substrate 1011 may also be other shapes, such as triangular, circular, and hexagonal, which is not limited by the present disclosure.

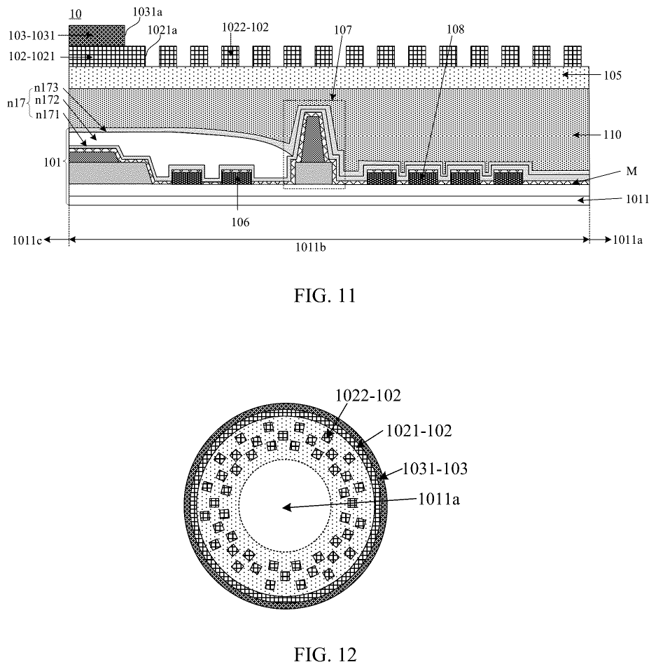

In some embodiments of the present disclosure, as the second optional implementation, referring to FIGS. 11 and 12, the first dimming layer 102 includes a second target portion 1021 with a continuous film layer disposed in the transition region 1011b. The second boundary 1021a of the second target portion 1021 close to the hole region 1011a is disposed within the transition region 1011b, and the second boundary 1021a is farther from the display region 1011c than the first boundary 1031a is, and the orthographic projection of the first boundary 1031a on the base substrate 1011 is within the orthographic projection of the second target portion 1021 on the base substrate 1011.

Moreover, the first dimming layer 102 further includes multiple second dimming island-shaped patterns 1022 evenly spaced in the transition region 1011b, the multiple second dimming island-shaped patterns 1022 are farther from the display region 1011c than the second target portion 1021 is. In this way, on the premise of improving flatness, the effect of the first dimming layer 102 as an intermediate transfer layer for transferring the pulling force is reduced. At the same time, any of the multiple second dimming island-shaped patterns 1022 is spaced from the second target portion 1021, i.e., there is no direct contact between the first target portion 1031 of the second dimming layer 103 and any second dimming island-shaped pattern 1022, which prevent the pulling force generated by the expansion of the first target portion 1031 of the second dimming layer 103 from being transferred through the second dimming island-shaped patterns 1022.

In some embodiments, referring to FIG. 12, the shape of the orthographic projection of the second dimming island-shaped pattern 1022 on the base substrate 1011 is a square. The shape of the orthographic projection of the second dimming island-shaped pattern 1022 on the base substrate 1011 may also be other shapes, such as triangular, circular, and hexagonal, which is not limited by the present disclosure.

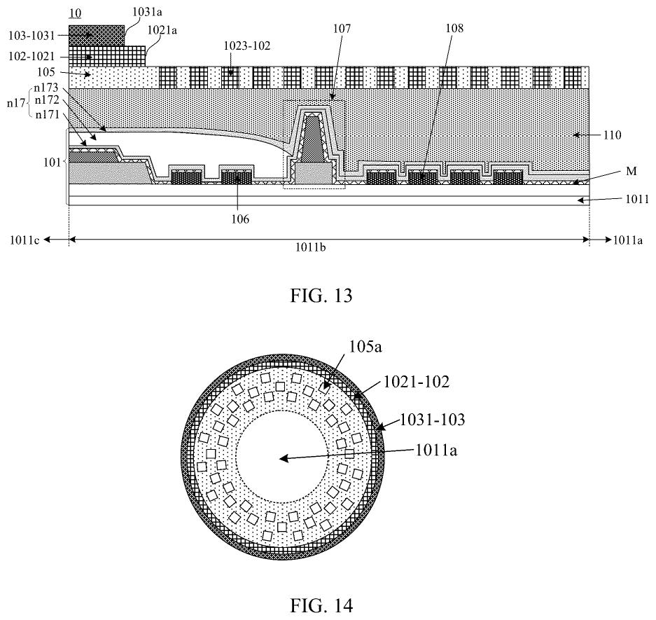

As the third optional implementation, in the case that the material of the first dimming layer 102 is different from the material of the first planarization layer 105, with reference to FIGS. 13 and 14, the first planarization layer 105 has multiple island-shaped recesses 105a evenly spaced in a portion where its orthographic projection on the base substrate 1011 neither overlaps with an orthographic projection of the first target portion 1031 on the base substrate 1011 nor overlaps with an orthographic projection of the second target portion 1021 on the base substrate 1011. The first dimming layer 102 includes multiple third dimming island-shaped patterns (not shown in the drawings) corresponding to the multiple island-shaped recesses 105a, and each of the third dimming island-shaped patterns is disposed within one of the island-shaped recesses 105a corresponding to the third dimming island-shaped pattern. In this way, the pulling force generated by the expansion of the first target portion 1031 of the second dimming layer 103 is only transferred variably between different materials, thereby weakening the transferring effect of the pulling force and reducing the possibility of separation of the film layers.

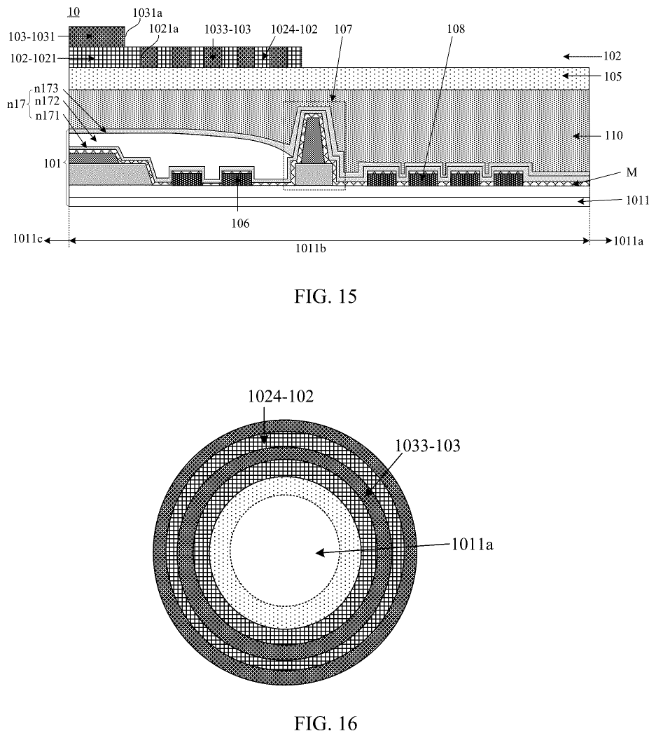

As the fourth optional implementation, referring to FIGS. 15 and 16, the second dimming layer 103 further includes multiple first dimming ring patterns 1033 spaced in the transition region 1011b. The orthographic projection of the first dimming ring patterns 1033 on the base substrate 1011 surrounds the hole region 1011a and the first dimming ring patterns 1033 are farther from the display region 1011c than the first target portion 1031 is. Any of the first dimming ring patterns 1033 is spaced from the first target portion 1031, which prevents the pulling force generated by expansion of the first target portion 1031 from being transferred along the first dimming ring patterns 1033. Moreover, the width of the first dimming ring pattern 1033 is small (the width ranges from 3 μm to 20 μm), so the pulling force generated by the expansion of the first dimming ring pattern 1033 is small. Such a small pulling force has minimal impact on the hole region 1011a.

Moreover, the first dimming layer 102 further includes multiple second dimming ring patterns 1024 spaced in the transition region 1011b. The orthographic projection of the second dimming ring patterns 1024 on the base substrate 1011 surrounds the hole region 1011a and the second dimming ring patterns 1024 are farther from the display region 1011c than the second target portion 1021 is. Any of the second dimming ring patterns 1024 is spaced from the second target portion 1021, which prevents the pulling force generated by expansion of the first target portion 1031 from being transferred along the second target portion 1021 and the second dimming ring pattern 1024. Moreover, the width of the second dimming ring pattern 1024 is small (the width ranges from 3 μm to 20 μm), and thus the second dimming ring pattern 1024 cannot be used as an intermediate transfer layer to transfer the pulling force to avoid significant impact on the hole region 1011a.

In addition, the multiple first dimming ring patterns 1033 and the multiple second dimming ring patterns 1024 are arranged in a staggered manner. In this way, the first dimming ring patterns 1033 and the second dimming ring patterns 1024 made of different materials are distributed discontinuously, thereby blocking the downward transfer of the pulling force and reducing the transmission effect of the pulling force.

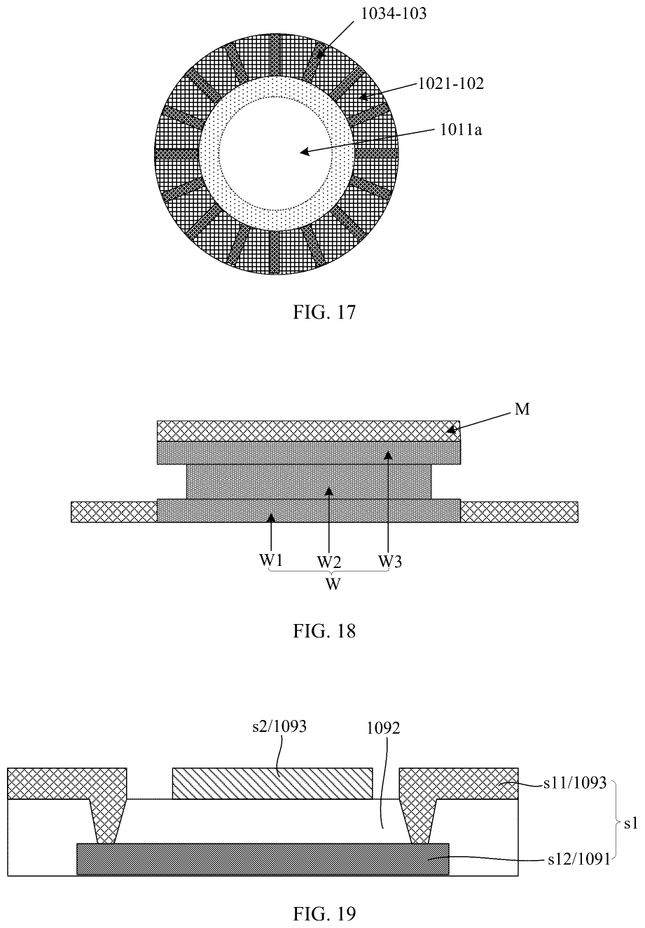

As the fifth optional implementation, referring to FIG. 17, the first dimming layer 102 includes multiple strip-shaped recesses disposed in the transition region 1011b. The multiple strip-shaped recesses are evenly spaced surrounding the hole region 1011a (e.g., ray-like distribution). The second dimming layer 103 includes multiple dimming strip-shaped patterns 1034 corresponding to the multiple strip-shaped recesses, and each dimming strip-shaped pattern 1034 is disposed within a strip-shaped recess corresponding to the dimming bar pattern 1034.

Referring to FIG. 17, 16 strip-shaped recesses are illustrated, but in practice, there is no specific limitation on the number of strip-shaped recesses, as long as the requirements of the preparation process can be met. In some embodiments, the distance between the ends, close to the hole region 1011a, of adjacent strip-shaped recesses may be greater than or equal to 3 μm.

It should be noted that the portion of the first dimming layer 102 disposed in the first target portion 1031 close to the hole region 1011a may also be of other shapes or arrangements, provided that the portion of the first dimming layer 102 disposed in the first target portion 1031 close to the hole region 1011a is patterned and spaced apart from the first target portion 1031. And, the portion of the second dimming layer 103 disposed in the second target portion 1021 close to the hole region 1011a may also be of other shapes or arrangements, provided that the portion of the second dimming layer 103 disposed in the second target portion 1021 close to the hole region 1011a is patterned and spaced apart from the second target portion 1021.

In some embodiments of the present disclosure, referring to FIGS. 1, and 3 to 17, the display substrate 101 further includes a first organic functional layer M disposed on one side of the base substrate 1011, and the first organic functional layer M is disposed in the display region 1011c and the transition region 1011b. The display substrate 101 further includes a first isolation pillar 106, a first barrier structure 107, and a second isolation pillar 108 disposed in the transition region 1011b and disposed sequentially in the direction away from the display region 1011c. The first organic functional layer M is broken at at least one of the first isolation pillar 106 and the second isolation pillar 108.

It should be noted that the water vapor and oxygen may be transported along the first organic functional layer M to the display region 1011c, and since the first organic functional layer M is broken at at least one of the isolation pillars, even if the water vapor and oxygen enter the first organic functional layer M from the side of the hole region 1011a in the display panel, the water vapor and oxygen can be blocked from entering the display region 1011c along the first organic functional layer M by the at least one isolation pillar. Further, the first organic functional layer M may be broken at both the first isolation pillar 106 and the second isolation pillar 108, so that water vapor and oxygen are further prevented from entering the display region 1011c. As a result, the pixel units 1012 of the display substrate 101 disposed in the display region 1011c are prevented from being corroded by the water vapor and oxygen, ensuring the display effect.

In some embodiments of the present disclosure, the first organic functional layer M is made of an organic material, which is prone to absorbing water and oxygen, and thus water vapor and oxygen may enter into the display substrate 101 from the first organic functional layer M on the side of the display substrate 101 located in the hole region 1011a. By causing the first organic functional layer M to break at at least one of the first isolation pillar 106 and the second isolation pillar 108, water vapor and oxygen are prevented from entering the display region 1011c along the first organic functional layer M.

In some embodiments, both the first isolation pillar 106 and the second isolation pillar 108 are annular structures surrounding the hole region 1011a. The display substrate 101 may include multiple first isolation pillars 106 and multiple second isolation pillars 108. Exemplarily, in FIG. 1, the display substrate 101 includes 2 first isolation pillars 106 and 4 second isolation pillars 108.

Further, as shown in FIG. 1, the extent to which the first boundary 1031a is away from the hole region 1011a may be measured by a distance h3 between the orthographic projection of the first boundary 1031a on the base substrate 1011 and the orthographic projection of the centerline of one of the multiple second isolation pillars 108 closest to the display region 1011c on the base substrate 1011. Exemplarily, the distance h3 is greater than or equal to 100 μm, so that the first target portion 1031 of the second dimming layer 103 is far from the hole region 1011a. Thus, the influence of the pulling force generated by the expansion of the first target portion 1031 on the hole region 1011a is reduced.

Alternatively, in the embodiments shown in FIG. 9, a distance h4 between the orthographic projection of the second boundary 1021a of the second target portion 1021 on the base substrate 1011 and the orthographic projection of the centerline of one of the multiple second isolation pillars 108 closest to the display region 1011c on the base substrate 1011 may be greater than or equal to 50 μm.

In some embodiments of the present disclosure, referring to FIG. 2, the base substrate 1011 is further provided with a periphery region 1011d surrounding the display region 1011c. The display substrate 101 further includes a second barrier structure (not shown in the figure) disposed in the periphery region 1011d. The second barrier structure is used to block the overflow of organic material located in the display region 1011c.

In some embodiments of the present disclosure, referring to FIG. 3, the display substrate 101 includes: a buffer layer n1, an active layer n2, a first gate insulation (GI) layer n3, a first gate layer n4, a second gate insulation layer n5, a second gate layer n6, an interlayer dielectric layer (ILD) n7, a first source-drain layer n8, a first planarization layer (PLN) n9, a second source-drain layer n10, a second planarization layer n11, an anode layer n12, a pixel definition layer (PDL) n13, a support layer (PS) n14, a light-emitting layer n15, a cathode layer (cathode) n16, and an encapsulation layer n17, which are stacked in sequence in the direction away from the base substrate 1011.

The first gate layer n4, the second gate layer n6, the first source-drain layer n8, the first planarization layer n9, the second source-drain layer n10, and the second planarization layer n11 are disposed in the display region 1011c, and the first gate insulation layer n3, the second gate insulation layer n5, and the interlayer dielectric layer n7 are disposed in the transition region 1011b and the display region 1011c.

In some embodiments of the present disclosure, the first isolation pillar 106 and the second isolation pillar 108 both include a target film layer W. Wherein the target film layer W is disposed at the first source-drain layer n8, and the orthographic projection of the target film layer W on the reference plane is I-shaped. By setting the target film layer W in the first isolation pillar 106 and the second isolation pillar 108 to be I-shaped, it is facilitated for the first organic functional layer M to break at the first isolation pillar 106 and the second isolation pillar 108, thereby preventing water vapor and oxygen from entering the display region 1011c.

In some embodiments, referring to FIG. 18, the target film layer W includes a first metal layer W1, a second metal layer W2, and a third metal layer W3 stacked sequentially in the direction away from the base substrate 1011. The etching rate of the second metal layer W2 is greater than the etching rate of the first metal layer W1, and greater than the etching rate of the third metal layer W3.

In the embodiments of the present disclosure, since the etching rate of the second metal layer W2 is larger and the etching rates of the first metal layer W1 and the third metal layer W3 are smaller, it is possible to make the target film layer W in an I-shaped based on the difference in the etching rates of the individual metal layers.

Exemplarily, assuming that the target film layer W and the first source-drain layer n8 are disposed in the same layer, since the first source-drain layer n8 is typically composed of triple layers of metal, such as stacked titanium (Ti), aluminum (Al), and titanium, the materials of the first metal layer W1 and the third metal layer W3 in the target film layer W may both be titanium, and the material of the second metal layer W2 may be aluminum.

In embodiments of the present disclosure, the first isolation pillar 106 and the second isolation pillar 108 may include other film layers in addition to the target film layer W. For example, both the first isolation pillar 106 and the second isolation pillar 108 include a gate pattern disposed in the same layer as the first gate layer n4, and a gate pattern disposed in the same layer as the second gate layer n6.

In embodiments of the present disclosure, the film layers included in the individual isolation pillars in the display substrate 101 may be different. Of course, the film layers included in the individual isolation pillars in the display substrate 101 may also be the same. The embodiments of the present disclosure do not limit this. Regardless of the film layer included in the respective isolation columns in the display substrate 101, it is sufficient to ensure that the first organic functional layer M breaks at at least one isolation pillar in the display substrate 101.

In some embodiments of the present disclosure, each pixel unit 1012 of the display substrate 101 disposed in the display region 1011c includes a pixel circuit and a light-emitting unit. The pixel circuit includes a storage capacitor and at least one thin-film transistor.

In some embodiments, the active layer n2 includes multiple active patterns. The first gate layer n4 includes multiple first gate patterns. The second gate layer n6 includes multiple second gate patterns. The first source-drain layer n8 includes multiple sources and multiple drains corresponding one-to-one with the multiple sources. The second source-drain layer n10 includes multiple connection patterns.

One active pattern, one first gate pattern, one source, and one drain form a thin-film transistor, and a source and a drain of each thin-film transistor are connected to the active pattern. One first gate pattern and one second gate pattern form a storage capacitor.

Referring to FIG. 3, the anode layer n12, the light-emitting film layer n15, and the cathode layer n16 in the display substrate 101 may form light-emitting units of the multiple pixel units 1012. The anode layer n12 includes multiple anode patterns. The light-emitting layer n15 includes a first organic functional layer M, a second organic functional layer, and a light-emitting pattern (only the light-emitting pattern is shown in the figure for representing the light-emitting layer n15). The anode layer n12, the second organic functional layer, and the light-emitting pattern are all disposed in the display region 1011c, and the cathode layer n16 is disposed in the transition region 1011b and the display region 1011c.

The anode layer n12, the second organic functional layer, and the light-emitting pattern are all disposed in the display region 1011c may mean: the anode layer n12, the second organic functional layer, and the light-emitting pattern are disposed only in the display region 1011c and are not disposed in the transition region 1011b. The first organic functional layer M includes a hole transport layer and an electron transport layer, and the second organic functional layer may include a hole injection layer and an electron injection layer.

Referring to FIG. 3, the pixel definition layer n13 in the display substrate 101 is provided with multiple hollow regions, each of which is configured to expose the anode pattern of a pixel unit 1012. The anode pattern of each pixel unit 1012 is connected to the drain of the thin-film transistor via a connection pattern.

In some embodiments of the present disclosure, the encapsulation layer n17 includes a first inorganic encapsulation layer n171, an organic encapsulation layer n172, and a second inorganic encapsulation layer n 173 that are stacked in sequence. The first inorganic encapsulation layer n171 and the second inorganic encapsulation layer n173 are located in the display region 1011c, the periphery region 1011d, and the transition region 1011b, and the organic encapsulation layer n172 is disposed on a side, close to the display region 1011c, of the second barrier structure.

Since the organic encapsulation layer n172 is made of organic material, the organic encapsulation layer n172 is not disposed in the periphery region 1011d and the transition region 1011b, water vapor and oxygen are avoided from the organic encapsulation layer n172 to enter the display region 1011c, thereby ensuring the encapsulation effect.

In some embodiments, the first inorganic encapsulation layer n171 is made of silicon nitride (SiNO), and the second inorganic encapsulation layer n173 is made of silicon nitride (SiN). The organic encapsulation layer n172 is made of a resin material. The resin may be a thermoplastic resin or a thermoset resin, the thermoplastic resin includes an acrylic (PMMA) resin, and the thermoset resin includes an epoxy resin.

In some embodiments, the first inorganic encapsulation layer n171 and the second inorganic encapsulation layer n173 are fabricated using a chemical vapor deposition (CVD) method. The organic encapsulation layer n172 is fabricated using an inkjet printing (IJP) method.

In some embodiments of the present disclosure, referring to FIG. 1, the first barrier structure 107 includes a first barrier dam 1071. The first barrier dam 1071 includes a first pattern t1 and a second pattern t2 sequentially stacked in a side away from the base substrate 1011. The first pattern t1 is located in the second planarization layer and the second pattern t2 is located in the pixel definition n13.

Of course, the first barrier structure 107 may include a first barrier dam 1071 and a second barrier dam (not shown in the figures) arranged in the direction close to the hole region 1011a. In some embodiments, the height of the first barrier dam 1071 and the height of the second barrier dam may be equal. Exemplarily, both the first barrier dam 1071 and the second barrier dam include a pattern of the second planarization layer and a pattern of the pixel definition layer n13. Of course, the height of the first barrier dam 1071 and the height of the second barrier dam may not be equal, which is not limited by the present disclosure.

In some embodiments of the present disclosure, referring to FIG. 3, the display panel 10 further includes a touch substrate 109 and a second planarization layer 110 disposed between the display substrate 101 and the first dimming layer 102 and stacked in the direction away from the display substrate 101. The touch substrate 109 includes a first touch electrode layer 1091, a touch insulation layer 1092, and a second touch electrode layer 1093 that are stacked in sequence disposed on the light-emitting side of the display substrate 101.

One of the first touch electrode layer 1091 and the second touch electrode layer 1093 includes a bridging electrode s12 of the multiple first touch electrodes s1, and another touch electrode layer includes a body electrode s11 of the multiple first touch electrodes s1 and multiple second touch electrodes s2. The bridging electrode and the body electrode are electrically connected through a via hole in the touch insulation layer 1092.

In some embodiments, referring to FIG. 19, the bridging electrode of the multiple first touch electrodes s1 is disposed in the first touch electrode layer 1091, and the body electrode s11 of the multiple first touch electrodes s1 and the multiple second touch electrodes s2 are disposed in the second touch electrode layer 1093. Alternatively, the body electrode s11 of the multiple first touch electrodes s1 and the multiple second touch electrode s2 are disposed in the first touch electrode layer 1091, the bridge electrode s12 of the multiple first touch electrodes s1 is disposed in the second touch electrode layer 1093.

Further, the touch substrate 109 also includes a driving circuit and a detecting circuit disposed in the periphery region 1011d. The driving circuit is electrically connected to the multiple first touch electrodes s1 for providing driving signals for the first touch electrodes s1. The detecting circuit is electrically connected to the second touch electrodes s2 for detecting a sensing signal between the first touch electrodes s1 and the second touch electrodes s2 received from the second touch electrodes s2.

In the process of the driving circuit providing a driving signal for the first touch electrode s1, the detecting circuit is able to detect a sensing signal between the first touch electrode s1 and the second touch electrode s2 received from the second touch electrode s2. If the user's finger is close to the display panel, the detecting circuit is able to detect a change in the sensing signal at the location of the user's finger, and determine the location at which the sensing signal has changed as the touch location.

In some embodiments, since the driving circuit is electrically connected to the first touch electrode s1, the first touch electrode s1 may be a transmitting (TX) electrode. Since the detecting circuit is electrically connected to the second touch electrode s2, the second touch electrode s2 may be a sense (RX) electrode.

Referring to FIG. 3, the portion of the first dimming layer 102 disposed in the display region 1011c includes multiple dimming patterns 1025, and the orthographic projection of the dimming patterns 1025 on the base substrate 1011 overlaps with the orthographic projection of the spacing between the adjacent pixel units 1012 on the base substrate 1011. Moreover, the angle between the extended surface of the sidewall of the dimming pattern 1025 and the bearing surface of the base substrate 1011 is an acute angle or an obtuse angle. That is, the extended surface of the side wall of the dimming pattern 1025 is inclined with respect to the bearing surface of the base substrate 1011.

In some embodiments, by setting the refractive index of the first dimming layer 102 less than the refractive index of the second dimming layer 103, the sides of the dimming pattern 1025 are able to refract and converge the light. That is, the light emitted from the pixel unit 1012 is able to be converged after being refracted at the sides of the dimming pattern 1025.

In some embodiments of the present disclosure, the second planarization layer 110 may be a whole film layer disposed in the display region 1011c, the transition region 1011b, and the hole region 1011a. Although the second planarization layer 110 is disposed between the display substrate 101 and the second dimming layer 103 and is also an intermediate transfer layer, the second planarization layer 110 and the second dimming layer 103 are farther apart in the longitudinal direction (perpendicular to the bearing surface of the base substrate 1011), and thus the second planarization layer 110 is not particularly effective as an intermediate transfer layer for transferring pulling force. That is, the second planarization layer 110 is set as a whole film layer will not have a significant effect on the hole region 1011a.

Alternatively, the second planarization layer 110 includes a fourth target portion with a continuous film layer disposed in the display region 1011c and the transition region 1011b. A fourth boundary of the fourth target portion close to the hole region 1011a is disposed within the transition region 1011b, and the distance between the fourth boundary and the display region 1011c is less than the distance between the fourth boundary and the hole region 1011a. That is, the second planarization layer 110 is inwardly retracted with respect to the hole region 1011a, thereby further reducing the transfer of pulling forces.

In some embodiments, the fourth boundary of the fourth target portion is inwardly retracted or wrapped with respect to the first boundary 1031a of the first target portion 1031, the second boundary 1021a of the second target portion 1021, and the third boundary 1051a of the third target portion 1051.

For example, in the case of the first boundary 1031a of the first target portion 1031, the second boundary 1021a of the second target portion 1021, and the third boundary 1051a of the third target portion 1051 shown in FIG. 6, the fourth boundary of the fourth target portion is farther from the display region 1011c than the third boundary 1051a of the third target portion 1051 is. That is, the fourth target portion, the third target portion 1051, the second target portion 1021, and the first target portion 1031 are sequentially inwardly retracted in the direction away from the hole region 1011a. In the case of the first boundary 1031a of the first target portion 1031, the second boundary 1021a of the second target portion 1021, and the third boundary 1051a of the third target portion 1051 shown in FIG. 7, the fourth boundary of the fourth target portion is closer to the display region 1011c than the third boundary 1051a of the third target portion 1051 is. That is, the fourth target portion, the third target portion 1051, the second target portion 1021, and the first target portion 1031 wrap sequentially toward close to the hole region 1011a.

In summary, the embodiments of the present disclosure provide a display panel, the display panel includes a display substrate, a first dimming layer, and a second dimming layer, and the display substrate includes a base substrate and multiple pixel units. The refractive index of the first dimming layer is different from the refractive index of the second dimming layer, so that the light emitted by the pixel units is converged, thereby increasing the forward light output of the pixel units and improving the display effect of the display panel. Moreover, since the distance between the first boundary of the first target portion, which is included in the second dimming layer and has a continuous film layer located in the display region and the transition region, and the hole region is longer, the influence of the pulling force generated by the expansion of the first target portion of the second dimming layer on the hole region is reduced, thereby reducing the possibility of separation of the film layer in the display panel and improving the yield rate of the display panel.

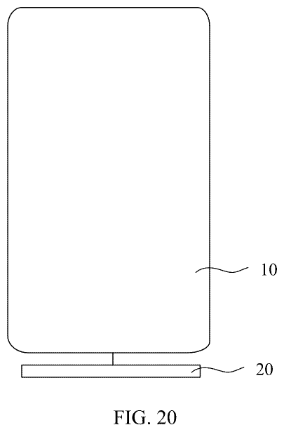

FIG. 20 is a schematic structural diagram of a display device according to some embodiments of the present disclosure. Referring to FIG. 20, the display device includes a power assembly 20 and the display panel 10 provided by any one of the above embodiments. The power assembly 20 is configured to power the display panel 10.

In some embodiments, the display device is an OLED display device, a quantum dot light emitting diodes (QLED) display device, an e-paper, a cell phone, a tablet computer, a television set, a monitor, a laptop computer, a digital photo frame, or a navigator, and any other product or component that has a display function as well as a fingerprint identification function.

Exemplarily, the display device is an active-matrix organic light emitting diode (AMOLED) display panel.

Since the display device may have basically the same technical effect as the display panel described in the previous embodiments, for the sake of brevity, the technical effects of the display device are not repeated herein.

The terms used in the embodiments of the present disclosure are used only to explain the embodiments of the present disclosure, and are not intended to limit the present disclosure. Unless otherwise defined, the technical or scientific terms used in the embodiments of the present disclosure are as they are usually understood by those of ordinary skill in the art to which the present disclosure pertains. The terms “first,” “second,” “third,” and the like used in this specification and in the claims do not denote any order, quantity or importance, but are merely intended to distinguish between different constituents. Similarly, the terms “a,” “an,” “the,” and the like are not meant to be limiting, but rather denote the presence of at least one. The terms “comprise,” “include,” and their derivatives mean that elements or articles appearing before “comprise” or “include” embody the elements or articles and their equivalent elements appearing behind “comprise” or “include,” not excluding any other elements or articles. The terms “connected”, “connected to each other” and similar words or phrases are not restricted to physical or mechanical connections, but may include direct and indirect electrical connections. The terms “upper”, “lower,” “left,” “right,” and the like are used only to indicate a relative positional relationship, and when the absolute position of the described object is changed, the relative positional relationship is also changed accordingly.

The foregoing descriptions are merely optional embodiments of the present disclosure and are not intended to limit the present disclosure. Any modification, equivalent replacement, and improvement within the spirit and principle of the present disclosure shall be included within the protection scope of the present disclosure.

1. A display panel, comprising a display substrate, wherein
the display substrate comprises:
a base substrate having a hole region, a transition region surrounding the hole region, and a display region surrounding the transition region; and
a plurality of pixel units disposed on one side of the base substrate and in the display region; and
the display substrate further comprises: a first dimming layer and a second dimming layer sequentially stacked on a side of the plurality of pixel units away from the base substrate, wherein a refractive index of the first dimming layer is different from a refractive index of the second dimming layer, and the first dimming layer and the second dimming layer are disposed at least in the display region;
wherein the second dimming layer comprises a first target portion with a continuous film layer disposed in the display region and the transition region, wherein a first boundary of the first target portion close to the hole region is disposed within the transition region, and a distance between the first boundary and the display region is less than a distance between the first boundary and the hole region.

2. The display panel according to claim 1, wherein the first dimming layer comprises a second target portion with a continuous film layer disposed in the transition region, wherein a second boundary of the second target portion close to the hole region is disposed within the transition region, and a distance between the second boundary and the display region is less than a distance between the second boundary and the hole region.

3. The display panel according to claim 2, wherein the second boundary is farther from the display region than the first boundary, and an orthographic projection of the first boundary on the base substrate falls within an orthographic projection of the second target portion on the base substrate; or
the first boundary is farther from the display region than the second boundary, and an orthographic projection of the first target portion on the base substrate covers an orthographic projection of the second boundary on the base substrate.

4. The display panel according to claim 2, further comprising: a color filter layer and a first planarization layer stacked in sequence away from the display substrate between the display substrate and the first dimming layer; wherein
the color filter layer comprises a plurality of color resistors disposed in the display region and a black matrix disposed in the display region, wherein an orthographic projection of each color resistor on the base substrate is overlapped with an orthographic projection of a light-emitting region of a pixel unit corresponding to the color resistor on the base substrate, light emitted from the pixel unit exits after passing through the color resistor, and an orthographic projection of the black matrix on the base substrate falls within between light-emitting regions of adjacent pixel units; and
the first planarization layer comprises a third target portion with a continuous film layer disposed in the display region and the transition region, wherein a third boundary of the third target portion close to the hole region is within the transition region, and a distance between the third boundary and the display region is less than a distance between the third boundary and the hole region.

5. The display panel according to claim 4, wherein
the second boundary is farther from the display region than the first boundary, and the third boundary is farther from the display region than the second boundary; and
an orthographic projection of the first boundary on the base substrate falls within an orthographic projection of the second target portion on the base substrate, and an orthographic projection of the second boundary on the base substrate falls within an orthographic projection of the third target portion on the base substrate.

6. The display panel according to claim 4, wherein
the second boundary is farther from the display region than the third boundary, and the first boundary is farther from the display region than the second boundary; and
an orthographic projection of the first target portion on the base substrate covers an orthographic projection of the second boundary on the base substrate, and an orthographic projection of the second target portion on the base substrate covers an orthographic projection of the third boundary on the base substrate.

7. The display panel according to claim 4, wherein the third boundary is farther from the display region than the second boundary, and the first boundary is farther from the display region than the third boundary; and
an orthographic projection of the second boundary on the base substrate falls within an orthographic projection of the third target portion on the base substrate, and an orthographic projection of the first target portion on the base substrate covers an orthographic projection of the second boundary on the base substrate and covers an orthographic projection of the third boundary on the base substrate.

8. The display panel according to claim 1, wherein the second dimming layer further comprises a plurality of first dimming island-shaped patterns evenly spaced in the transition region;
wherein the plurality of first dimming island-shaped patterns are closer to the hole region than the first target portion and any of the plurality of first dimming island-shaped patterns is spaced from the first target portion.

9. The display panel according to claim 8, wherein the first dimming layer comprises a second target portion with a continuous film layer disposed in the transition region, wherein a second boundary of the second target portion close to the hole region is within the transition region;
wherein the second boundary is farther from the display region than the plurality of first dimming island-shaped patterns, and an orthographic projection of the plurality of first dimming island-shaped patterns on the base substrate is within an orthographic projection of the second target portion on the base substrate.

10. The display panel according to claim 1, wherein
the first dimming layer comprises a second target portion with a continuous film layer disposed in the transition region, wherein a second boundary of the second target portion close to the hole region is disposed within the transition region, the second boundary is farther from the display region than the first boundary, and an orthographic projection of the first boundary on the base substrate falls within an orthographic projection of the second target portion on the base substrate; and
the first dimming layer further comprises a plurality of second dimming island-shaped patterns evenly spaced in the transition region, wherein the plurality of second dimming island-shaped patterns are farther from the display region than the second target portion, and any of the plurality of second dimming island-shaped patterns is spaced from the second target portion.

11. The display panel according to claim 1, further comprising: a first planarization layer disposed between the display substrate and the first dimming layer; wherein
the first dimming layer and the first planarization layer are made of different materials;
the first planarization layer has a plurality of island-shaped recesses evenly spaced in a portion where an orthographic projection of the first planarization layer on the base substrate is neither overlapped with an orthographic projection of the first target portion on the base substrate nor overlapped with an orthographic projection of the second target portion on the base substrate; and
the first dimming layer comprises a plurality of third dimming island-shaped patterns corresponding to the plurality of island-shaped recesses, wherein each of the plurality of third dimming island-shaped patterns is disposed within an island-shaped recess corresponding to the third dimming island-shaped pattern.

12. The display panel according to claim 1, wherein
the second dimming layer further comprises a plurality of first dimming ring patterns spaced in the transition region, wherein an orthographic projection of the plurality of first dimming ring patterns on the base substrate surrounds the hole region and the plurality of first dimming ring patterns are farther from the display region than the first target portion, and any of the plurality of first dimming ring patterns is spaced from the first target portion;
the first dimming layer further comprises a plurality of second dimming ring patterns spaced in the transition region, wherein an orthographic projection of the plurality of the second dimming ring patterns on the base substrate surrounds the hole region and the plurality of the second dimming ring patterns are farther from the display region than the second target portion, and any of the plurality of second dimming ting patterns is spaced from the second target portion;
wherein the plurality of first dimming ring patterns and the plurality of second dimming ring patterns are arranged in a staggered manner.

13. The display panel according to claim 1, wherein
the first dimming layer comprises a plurality of strip-shaped recesses disposed in the transition region, wherein the plurality of strip-shaped recesses are evenly spaced around the hole region; and
the second dimming layer comprises a plurality of dimming strip-shaped patterns corresponding to the plurality of strip-shaped recesses, wherein each of the plurality of dimming strip-shaped pattern is disposed within a strip-shaped recess corresponding to the dimming strip-shaped pattern.

14. The display panel according to claim 1, wherein the display substrate further comprises a first organic functional layer disposed on one side of the base substrate, the first organic functional layer being disposed in the display region and the transition region; and the display substrate further comprises a first isolation pillar, a first barrier structure, and a second isolation pillar in the transition region disposed sequentially in a direction away from the display region;
wherein the first organic functional layer is broken at at least one of the first isolation pillar and the second isolation pillar.

15. The display panel according to claim 14, wherein the display substrate comprises a buffer layer, an active layer, a first gate insulation layer, a first gate layer, a second gate insulation layer, a second gate layer, an interlayer dielectric layer, a first source-drain layer, a first planarization layer, a second source-drain layer, a second planarization layer, an anode layer, a pixel definition layer, a support layer, a light-emitting layer, a cathode layer, and an encapsulation layer that are stacked in sequence in a direction away from the base substrate;
the light-emitting layer comprises the first organic functional layer, a second organic functional layer, and a light-emitting pattern, wherein the first organic functional layer comprises a hole transport layer and an electron transport layer, and the second organic functional layer comprises a hole injection layer and an electron injection layer; and
the encapsulation layer includes a first inorganic encapsulation layer, an organic encapsulation layer, and a second inorganic encapsulation layer that are stacked in sequence, wherein the first inorganic encapsulation layer and the second inorganic encapsulation layer are disposed in the display region, and the periphery region, the transition region, and the organic encapsulation layer are disposed on a side, close to the display region, of the first barrier structure.

16. The display panel according to claim 15, wherein the first isolation pillar and the second isolation pillar both comprise a target film layer;
wherein the target film layer is disposed in the first source-drain layer, and an orthographic projection of the target film layer on a reference plane is I-shaped, wherein the reference plane is perpendicular to a bearing surface of the base substrate.

17. The display panel according to claim 15, wherein the display substrate comprises a plurality of second isolation pillars;
wherein a distance between an orthographic projection of the first boundary on the base substrate and an orthographic projection of a centerline of one of the plurality of second isolation pillars closest to the display region on the base substrate is greater than or equal to 100 micrometers.

18. The display panel according to claim 1, further comprising: a touch substrate and a second planarization layer disposed between the display substrate and the first dimming layer and stacked in a direction away from the display substrate; wherein
the touch substrate comprises a first touch electrode layer, a touch insulation layer, and a second touch electrode layer that are stacked in sequence;
wherein one of the first touch electrode layer and the second touch electrode layer comprises a bridge electrode of a plurality of first touch electrodes, and another of the first touch electrode layer and the second touch electrode layer comprises a plurality of second touch electrodes and a body electrode of the plurality of first touch electrodes, wherein the bridge electrode and the body electrode are electrically connected through a via in the touch insulation layer.

19. The display panel according to claim 18, wherein the second planarization layer comprises a fourth target portion with a continuous film layer disposed in the display region and the transition region, wherein a fourth boundary of the fourth target portion close to the hole region is within the transition region, and a distance between the fourth boundary and the display region is less than a distance between the fourth boundary and the hole region.

20. A display device, comprising a power assembly and a display panel, wherein the display panel comprises a display substrate, wherein the display substrate comprises: a base substrate having a hole region, a transition region surrounding the hole region, and a display region surrounding the transition region; and a plurality of pixel units disposed on one side of the base substrate and in the display region;
the display substrate further comprises: a first dimming layer and a second dimming layer sequentially stacked on a side of the plurality of pixel units away from the base substrate. wherein a refractive index of the first dimming layer is different from a refractive index of the second dimming layer, and the first dimming layer and the second dimming layer are disposed at least in the display region;
wherein the second dimming layer comprises a first target portion with a continuous film layer disposed in the display region and the transition region, wherein a first boundary of the first target portion close to the hole region is disposed within the transition region, and a distance between the first boundary and the display region is less than a distance between the first boundary and the hole region; and
wherein the power assembly is configured to power the display panel.
